(19) United States
(12) Patent Application Publication
(10) Pub. No.: US 2016/0300905 A1
(43) Pub. Date: Oct. 13, 2016

(54) Semiconductor Device Including a Superjunction Structure with Drift Regions and Compensation Structures

(71) Applicant: Infineon Technologies Austria AG, Villach (AT)

(72) Inventors: Uwe Wahl, Munich (DE); Franz Hirler, Isen (DE); Hans Weber, Bayerisch Gmain (DE)

(21) Appl. No.: 15/185,582

(22) Filed: Jun. 17, 2016

Related U.S. Application Data
(63) Continuation of application No. 13/475,302, filed on May 18, 2012.

(51) Int. Cl. H01L 29/06; H01L 29/78; H01L 29/66; H01L 29/872; H01L 29/423; H01L 29/40; H01L 29/10; H01L 29/739

(52) U.S. Cl. CPC H01L 29/0634; H01L 29/1095; H01L 29/7811; H01L 29/7397; H01L 29/872; H01L 29/7813; H01L 29/4236; H01L 29/407; H01L 29/404; H01L 29/66333; H01L 29/66712; H01L 29/7395; H01L 29/66143

(57) ABSTRACT

A vertical semiconductor device includes a semiconductor body having a first surface and a second surface opposite to the first surface, a first trench including a dielectric, a gate electrode and a field electrode, the first trench extending into the semiconductor body from the first surface, and a superjunction structure in the semiconductor body. The superjunction structure includes drift regions of a first conductivity type and compensation structures alternately disposed in a first direction parallel to the first surface.

### BACKGROUND

A key component in semiconductor applications is a solid state switch. As an example, switches turn loads of automotive applications or industrial applications on and off. Solid state switches typically include, for example, field effect transistors (FETs) like metal-oxide-semiconductor FETs (MOSFETs) or insulated gate bipolar transistors (IGBTs).

Key demands on solid state switches are low on-state resistance (Ron) and high breakdown voltage (Vbr). Minimizing the on-state resistance is often at the expense of the breakdown voltage, Therefore, a trade-off between Ron and Vbr has to be met.

Superjunction structures are widely used to improve a trade-off between on-state resistance and the breakdown voltage. In a conventional n-channel superjunction device, alternating n-doped and p-doped regions replace one comparatively lower n-doped drift zone. In an on-state, current flows through the n-doped regions of the superjunction device which lowers the Ron, In an off or blocking state, the p-doped regions and the n-doped regions deplete or compensate each other to provide a high Vbr. A compensation structure design is one key element for improving the trade-off between Ron and Vbr.

Accordingly, a superjunction device with an improved compensation structure design is needed.

### SUMMARY

According to an embodiment of a semiconductor device, the semiconductor device includes a semiconductor body having a first surface and a second surface opposite to the first surface. The semiconductor device further includes a superjunction structure in the semiconductor body. The superjunction structure includes drift regions of a first conductivity type and compensation structures alternately disposed in a first direction parallel to the first surface. Each of the compensation structures includes a first semiconductor region of a second conductivity type complementary to the first conductivity type and a first trench including a second semiconductor region of the second conductivity type adjoining the first semiconductor region. The first semiconductor region and the first trench are disposed one after another in a second direction perpendicular to the first surface.

According to an embodiment of a semiconductor device, the semiconductor device includes a semiconductor body having a first surface and a second surface opposite to the first surface. The semiconductor device further includes a first trench including a dielectric, a gate electrode and a field electrode. The first trench extends into the semiconductor body from the first surface. The semiconductor device further includes a superjunction structure in the semiconductor body. The superjunction structure includes drift regions of a first conductivity type and compensation structures alternately disposed in a first direction parallel to the first surface.

According to another embodiment of a semiconductor device, the semiconductor device includes a semiconductor body having a first surface and a second surface opposite to the first surface. The semiconductor device further includes a superjunction structure in the semiconductor body. The superjunction structure includes drift regions of a first conductivity type and compensation regions of a second conductivity type complementary to the first conductivity type. The drift regions and the compensation regions are alternately disposed in a first direction parallel to the first surface. The semiconductor device further includes a body region of the second conductivity type at the first surface. The semiconductor device further includes a first trench in the semiconductor body having a first one of the compensation regions at a first sidewall of the first trench, a second one of the compensation regions at a second sidewall of the first trench opposite to the first sidewall and a first one of the drift regions between the first and second ones of the compensation regions. The semiconductor device further includes third and fourth ones of the compensation regions adjoining the first and second ones of the compensation regions, respectively. The third and fourth ones of the compensation regions are located between the body region and the first and second ones of the compensation regions, respectively, or between the first and second ones of the compensation regions and the second surface, respectively.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the present invention and are incorporated in and constitute a part of the specification. The drawings illustrate embodiments of the present invention and together with the description serve to explain principles of the invention. Other embodiments of the invention and many of the intended advantages will be readily appreciated as they become better understood by reference to the following detailed description. The elements of the drawings are not necessarily to scale relative to each other. Like reference numerals designate corresponding similar parts.

FIGS. 1 to 3 are cross sectional views of embodiments of planar gate superjunction semiconductor devices including a charge compensation structure of alternately arranged trench compensation structures and drift regions.

FIGS. 4 to 6 are cross sectional views of embodiments of vertical channel superjunction semiconductor devices including a charge compensation structure of alternately arranged trench compensation structures and drift regions.

FIG. 7 is a cross sectional view of one embodiment of a planar gate superjunction semiconductor device having a trench compensation structure complementary to the embodiment illustrated in FIG. 1.

FIGS. 8A to 8E are schematic cross sectional views illustrating different processes during manufacture of a superjunction semiconductor device according to an embodiment.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described as part of one embodiment can be used in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, similar elements or manufacturing processes are designated by similar references in the different drawings if not stated otherwise.

As employed in the specification, the term “electrically coupled” is not meant to mean that the elements must he directly coupled together. Instead, intervening elements may be provided between the “electrically coupled” elements. As an example, none, part, or all of the intervening element(s) may be controllable to provide a low-ohmic connection and, at another time, a non-low-ohmic connection between the “electrically coupled” elements. The term “electrically connected” intends to describe a low-ohmic electric connection between the elements electrically connected together, e.g., a connection via a metal and/or highly doped semiconductor.

Some Figures refer to relative doping concentrations by indicating “−” or “+” next to the doping type. For example, “n⁻” means a doping concentration which is less than the doping concentration of an “n”-doping region while an “n⁺”-doping region has a larger doping concentration than the “n”-doping region. Doping regions of the same relative doping concentration may or may not have the same absolute doping concentration. For example, two different n⁺-doped regions can have different absolute doping concentrations. The same applies, for example, to an n⁻-doped and a p⁺-doped region. In the embodiments described below, a conductivity type of the illustrated semiconductor regions is denoted n-type or p-type, in more detail one of n⁻-type, n-type, n⁺-type, p⁻-type, p-type and p⁺-type. In each of the illustrated embodiments, the conductivity type of the illustrated semiconductor regions may be vice versa. In other words, in an alternative embodiment to any one of the embodiments described below, an illustrated p-type region may be n-type and an illustrated n-type region may be p-type.

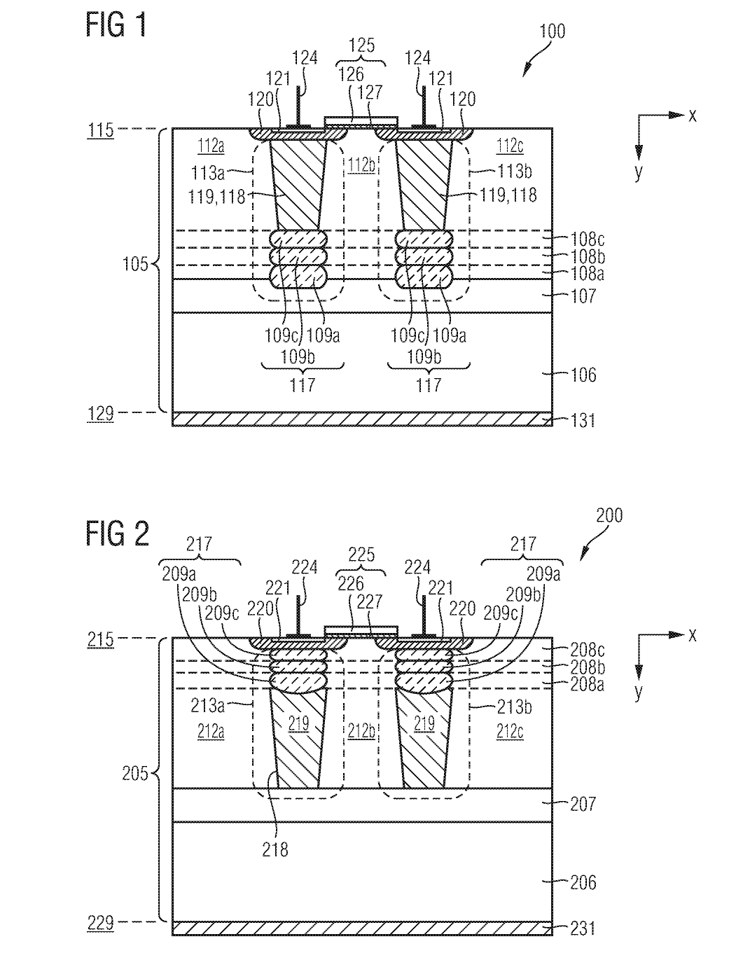

FIG. 1 is a cross sectional view of a superjunction semiconductor device 100 according to an embodiment. The superjunction semiconductor device 100 includes a semiconductor body 105, e.g. a semiconductor substrate 106 including one or more epitaxial layers thereon, e.g. an optional epitaxial base layer 107. According to an embodiment, the semiconductor substrate 106 is made of silicon. According to other embodiments, the semiconductor substrate 106 is made of a material other than silicon.

A superjunction structure is formed in the semiconductor body 105, wherein the superjunction structure includes drift regions 112a . . . 112c of a first conductivity type and compensation structures 113a, 113b alternately disposed in a first direction x parallel to a first surface 115 of the semiconductor body 105. Each of the compensation structures 113a, 113b includes a first semiconductor region 117 of a second conductivity type complementary to the first conductivity type and a first trench 118 including a second semiconductor region 119 of the second conductivity type adjoining the first semiconductor region 117. The first trench 118 and the first semiconductor region 117 are disposed one after another in a second direction y perpendicular to the first surface 115.

The superjunction semiconductor device 100 further includes a body region 120 of the second conductivity type and a source region 121 of the first conductivity type at the first surface 115. An electrical contact to the source region 121 is schematically illustrated by a contact 124. As an example, the contact 124 may be a groove-like contact and extend into the semiconductor body 105 electrically contacting the source region 121 and the body region 120 via sidewalls and/or a bottom side. As a further or additional example, the contact 124 may adjoin the body region 120 or a highly doped body contact region along a direction perpendicular to the cross sectional plane illustrated in FIG. 1.

The superjunction semiconductor device 100 further includes a gate structure 125 on the first surface 115. The gate structure includes 125 includes a gate electrode 126 and a gate dielectric 127 between the gate electrode 126 and the semiconductor body 105. In the embodiment illustrated in FIG. 1, the gate structure 125 is a planar gate.

At a second surface 129 of the semiconductor body 105 opposite to the first surface 115, a drain contact 131 is electrically coupled to the drift regions 112a . . . 112c.

The first semiconductor region 117 may be formed by a multi-epitaxial growth technology, for example, in which the processes of introducing impurities into the certain areas of the semiconductor body 105 by ion implantation, which has excellent impurity concentration control performance, and epitaxial growth are performed repeatedly. In case the first semiconductor region 117 is made up of one single layer, the above process is only carried out once. As a first example, a first layer of the first conductivity type, e.g. an n-type, may be grown epitaxially on the optional base layer 107. After completion of that layer, impurities of the second conductivity type, e.g. boron (B) for p-doping in silicon, are implanted into regions of the first layer that will become regions of the second conductivity type. Epitaxial growth and ion implantation are repeated until a desired drift layer thickness is achieved, and then thermal diffusion may be carried out to form consecutive n-type and p-type regions. As a second example, a first undoped layer may be grown by epitaxy on the optional base layer 107. After completion of that layer, impurities of the first conductivity type, e.g. phosphor (P) for n-doping in silicon, and impurities of the second conductivity type, e.g. boron for p-doping in silicon, are implanted into regions of the first layer that will become regions of the first and second conductivity type. Epitaxial growth and ion implantation are repeated until a desired drift layer thickness is achieved, and then the al diffusion may be carried out to form consecutive n-type and p-type regions. Depending upon parameters such as thermal budget during thermal diffusion, a degree of diffusion of impurities from one layer into another layer may vary. In the embodiment illustrated in FIG. 1, three epitaxial layers 108a . . . 108c are subsequently grown on each other by a technique like the above-described multi-epitaxial growth technique. The first semiconductor layer 117 may include one or a plurality of consecutive and overlapping semiconductor zones 109a . . . 109c shaped as bubbles, The number of three epitaxial layers 108a . . . 108c illustrated in FIG. 1 is one example. The number of epitaxial layers may be adapted to the specific requirements and may differ from three, e.g. be smaller than three or larger than three.

The first trench 118 may be formed in the semiconductor body 105 by etching, e.g. by using a plasma dry etching process, for example. The second semiconductor region 119 of the second conductivity type may be formed by filling up the first trench 118 with a semiconductor material of the second conductivity type. As an example, the second semiconductor region 119 may be formed by a CVD (Chemical Vapor Deposition) process using a layer gas including silicon atoms, for example, SiH₄, Si₂H₄, Si₂H₆ or SiH₂Cl₂. Doping of the second semiconductor region 119 may be carried out in-situ by adding a dopant gas to the layer gas. As an example, the dopant gas may include a group III element for p-doping in silicon, e.g. B₂H₅, or a group V element for n-doping in silicon, e.g. PH₃. As a further example, the second semiconductor region 119 may be formed by first forming a liner on sidewalls and on a bottom side of the first trench 118, e.g. by a layer deposition process such as CVD. Subsequently, the liner may be highly doped by using an ion implantation process, for example. Then, the first trench 118 may be filled up with intrinsic or nearly intrinsic semiconductor material and dopants may be diffused from the liner into the previously intrinsic or nearly intrinsic semiconductor material within the first trench 118 resulting in the second semiconductor region 119 of the second conductivity type.

Further processes, e.g. formation of the body region 120, the source region 121, the gate structure 125, the drain contact 131 and further elements may follow or may partly be carried out before or between the processes described above.

The body region 120, the second semiconductor region 119 and the first semiconductor region 117 constitute one continuous semiconductor region of the second conductivity type.

FIG. 2 is a cross sectional view of a superjunction semiconductor device 200 according to another embodiment. Similar to the superjunction semiconductor device 100 illustrated in FIG. 1, the superjunction semiconductor device 200 includes a semiconductor body 205, e.g. a semiconductor substrate 206 including one or more epitaxial layers thereon, e.g. an optional epitaxial base layer 207. According to an embodiment, the semiconductor substrate 206 is made of silicon. According to other embodiments, the semiconductor substrate 206 is made of a material other than silicon.

A superjunction structure is formed in the semiconductor body 205, wherein the superjunction structure includes drift regions 212a . . . 212c of a first conductivity type and compensation structures 213a, 213b alternately disposed in a first direction x parallel to a first surface 215. Each of the compensation structures 213a, 213b includes a first semiconductor region 217 of a second conductivity type complementary to the first conductivity type and a first trench 218 including a second semiconductor region 219 of the second conductivity type adjoining the first semiconductor region. The first semiconductor region 217 and the first trench 218 are disposed one after another in a second direction y perpendicular to a first surface 215 of the semiconductor body 205. Similar to the embodiment illustrated in FIG. 1, three epitaxial layers 208a . . . 208c are subsequently grown on each other by a technique like the above-described multi-epitaxial growth technique. The first semiconductor layer 217 may include one or a plurality of consecutive and overlapping semiconductor zones 209a . . . 209c shaped as bubbles. The number of three epitaxial layers 208a . . . 208c illustrated in FIG. 2 is one example. The number of epitaxial layers may be adapted to the specific requirements and may differ from three, e.g. be smaller than three or larger than three.

The superjunction semiconductor device 200 further includes a body region 220 of the second conductivity type and a source region 221 of the first conductivity type at the first surface 215. An electrical contact to the source region 221 is schematically illustrated by a contact 224. As an example, the contact 224 may be a groove-like contact and extend into the semiconductor body 205 electrically contacting the source region 221 and the body region 220 via sidewalls and/or a bottom side. As a further or additional example, the contact 224 may adjoin the body region 220 or a highly doped body contact region along a direction perpendicular to the cross sectional plane illustrated in FIG. 2.

The superjunction semiconductor device 200 further includes a gate structure 225 on the first surface 215. The gate structure includes 225 includes a gate elect ode 226 and a gate dielectric 227 between the gate electrode 226 and the semiconductor body 205. In the embodiment illustrated in FIG. 2, the gate structure 225 is a planar gate.

At a second surface 229 of the semiconductor body 205 opposite to the first surface 215, a drain contact 231 is electrically coupled to the drift regions 212a . . . 212c.

Formation of the first semiconductor region 217, the first trench 218 and the second semiconductor region 219 may be carried out as described with reference to FIG. 1.

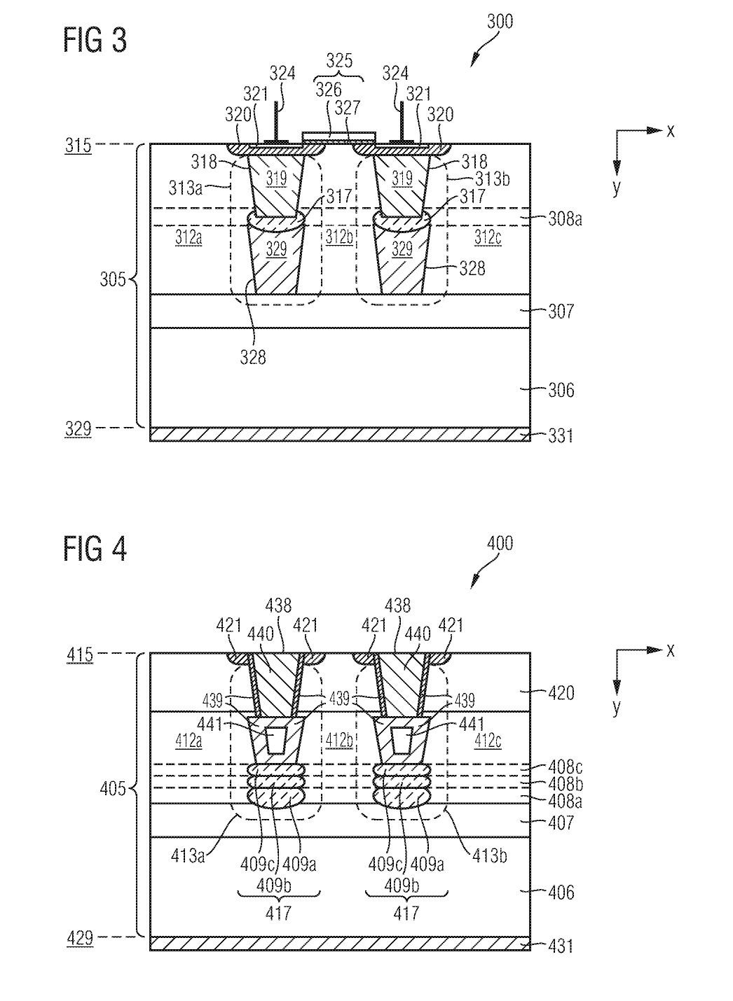

FIG. 3 is a cross sectional view of a superjunction semiconductor device 300 according to another embodiment. Similar to the superjunction semiconductor device 100 illustrated in FIG. 1, the superjunction semiconductor device 300 includes a semiconductor body 305, e.g. a semiconductor substrate 306 including one or more epitaxial layers thereon, e.g. an optional epitaxial base layer 307. According to an embodiment, the semiconductor substrate 306 is made of silicon. According to other embodiments, the semiconductor substrate 306 is made of a material other than silicon.

A superjunction structure is formed in the semiconductor body 305, wherein the superjunction structure includes drift regions 312a . . . 312c of a first conductivity type and compensation structures 313a, 313b alternately disposed in a first direction x parallel to a first surface 315 of the semiconductor body 305. Each of the compensation structures 313a, 13b includes a first semiconductor region 317 of a second conductivity type complementary to the first conductivity type, a first trench 318 including a second semiconductor region 319 of the second conductivity type adjoining a bottom side of the first semiconductor region 317 and a second trench 328 including a second semiconductor region 329 of the second conductivity type adjoining a top side of the first semiconductor region 317. The second trench 328, the first semiconductor region 317 and the first trench 318 are disposed one after another in a second direction y perpendicular to the first surface 315.

The superjunction semiconductor device 300 further includes a body region 320 of the second conductivity type and a source region 321 of the first conductivity type at the first surface 315. An electrical contact to the source region 321 is schematically illustrated by a contact 324. As an example, the contact 324 may be a groove-like contact and extend into the semiconductor body 305 electrically contacting the source region 321 and the body region 320 via sidewalls and/or a bottom side. As a further or additional example, the contact may adjoin the body region 320 or a highly doped body contact region along a direction perpendicular to the cross sectional plane illustrated in FIG. 3.

The superjunction semiconductor device 300 further includes a gate structure 325 on the first surface 315. The gate structure includes 325 includes a gate electrode 326 and a gate dielectric 327 between the gate electrode 326 and the semiconductor body 305. In the embodiment illustrated in FIG. 3, the gate structure 325 is a planar gate.

At a second surface 329 of the semiconductor body 305 opposite to the first surface 315, a drain contact 331 is electrically coupled to the drift regions 312a . . . 312c.

Formation of the first semiconductor region 317, the first trench 318 and the second semiconductor region 319 may be carried out as described with reference to FIG. 1. The second trench 328 and the third semiconductor region 329 may be formed as described with regard to the first trench 118 and the second semiconductor region 119 illustrated in FIG. 1.

In the embodiment illustrated in FIG. 3, the first semiconductor region 307 is formed in one single layer 308a by the above-described multi-epitaxial growth technique. A single epitaxial layer 308a illustrated in FIG. 3 is one example. The number of epitaxial layers may be adapted to the specific requirements and may be larger than one, e.g. correspond to three including three consecutive and overlapping zones as illustrated in FIGS. 1 and 2.

According to one embodiment, the first and second trenches 318, 328 have a common depth along the direction y. This may lead to a symmetrical electrical field distribution along the direction y. According to another embodiment, the first and second trenches 318, 328 have different depths along the direction y. This may lead to an asymmetrical electrical field distribution along the direction y, The depths of the first and second trenches 318, 328 may thus be adapted to the specific requirements on the electric field distribution, for example.

The above described embodiments allow realizing small cell pitches and high aspect ratios of the p-doped and n-doped compensation structures. Further, the doping along a vertical direction may be varied in the compensation structure different from the drift zone, e.g. in p-columns next to n-drift zones, and thereby the electric field distribution may be adapted to the specific needs of the application.

FIG. 4 is a cross sectional view of a superjunction semiconductor device 400 according to another embodiment. The superjunction semiconductor device 400 includes a semiconductor body 405, e.g. a semiconductor substrate 406 including one or more epitaxial layers thereon, e.g. an optional epitaxial base layer 407. According to an embodiment, the semiconductor substrate 406 is made of silicon. According to other embodiments, the semiconductor substrate 406 is made of a material other than silicon.

The superjunction semiconductor device 400 further includes a first trench 438 including a dielectric 439, a gate electrode 440 and a field electrode 441. The first trench 438 extends into the semiconductor body 405 from a first surface 415 of the semiconductor body 405.

A superjunction structure is formed in the semiconductor body 405. The superjunction structure includes drift regions 412a . . . 412c of a first conductivity type and compensation structures 413a, 413b alternately disposed in a first direction x parallel to the first surface 415 of the semiconductor body 405.

Each of the compensation structures 413a, 413b includes a first semiconductor region 417 of a second conductivity type complementary to the first conductivity type and the field electrode 441 surrounded by the dielectric 439. The field electrode 441 and the first semiconductor region 417 are disposed one after another in a second direction y perpendicular to the first surface 415. The first trench 438 may be formed by a single etch process or by a plurality of etch processes, e.g. by two etch processes. As an example, a bottom part of the first trench 438 may be etched in a first etch process followed by formation of the field electrode 441. Then, an epitaxial layer may be grown until the semiconductor body 405 reaches the first surface 415 as illustrated in FIG. 4. Thereafter, a gate dielectric and a gate electrode 440 may be formed.

The superjunction semiconductor device 400 further includes a body region 420 of the second conductivity type and a source region 421 of the first conductivity type at the first surface 415. The superjunction semiconductor device 400 further includes the gate electrode 440 in the first trench 438. A part of the dielectric 439 between the gate electrode 440 and the body region 420 constitutes the gate dielectric. A conductivity in a channel region along the direction y between the source region 421 and each one of the drift regions 412a . . . 412c can be controlled via a voltage applied to the gate electrode 440. In the embodiment illustrated in FIG. 4, the channel is a vertical channel.

At a second surface 429 of the semiconductor body 405 opposite to the first surface 4 5, a drain contact 431 is electrically coupled to the drift regions 412a . . . 412c.

Formation of the first semiconductor region 417 may be carried out as described with reference to the first semiconductor region 117 illustrated in FIG. 1. The first semiconductor region 417 may include one or a plurality of consecutive and overlapping semiconductor zones 409a . . . 409c shaped as bubbles in consecutive epitaxial layers 408a . . . 408c. The number of three epitaxial layers 408a . . . 408c illustrated in FIG. 4 is one example. The number of epitaxial layers may be adapted to the specific requirements and may differ from three, e.g. be smaller than three or larger than three.

The field electrode 441 in the first trench 418 allows for a lateral compensation. Further, when turning on the semiconductor device 400, a further channel current may flow in that part of the drift zone at the dielectric opposite to the field electrode 441, As an example, the further channel current may be a hole current in case of a p-type body region 420. Or, alternatively, the channel current may be an electron current in case of an n-type body region 420. Other than in trenches filled up with a dielectric, discharge of the first semiconductor region 417 is possible via the further channel current. The field electrode 441 allows to reduce a gate charge and may be electrically coupled to a voltage of the source region 421.

According to another embodiment, the first semiconductor region 417 is replaced by a trench including or filled up with a semiconductor material of the second conductivity type.

FIG. 5 is a cross sectional view of a superjunction semiconductor device 500 according to another embodiment. The superjunction semiconductor device 500 includes a semiconductor body 505, e.g. a semiconductor substrate 506 including one or more epitaxial layers thereon, e.g. an optional epitaxial base layer 507. According to an embodiment, the semiconductor substrate 506 is made of silicon. According to other embodiments, the semiconductor substrate 506 is made of a material other than silicon.

The superjunction semiconductor device 500 further includes a first trench 538 including a dielectric 539, a gate electrode 540 and a field electrode 541. The first trench 538 extends into the semiconductor body 505 from a first surface 515 of the semiconductor body 505.

A superjunction structure is formed in the semiconductor body 505. The superjunction structure includes drift regions 512a . . . 512c of a first conductivity type and compensation structures 513a, 513b alternately disposed in a first direction x parallel to the first surface 515 of the semiconductor body 505.

Each of the compensation structures 513a, 513b includes a first semiconductor region 517 of a second conductivity type complementary to the first conductivity type, a second trench 558 and a compensation field electrode 561 surrounded by a dielectric 562 in the second trench 558. The second trench 558 and the first semiconductor region 517 are disposed one after another in a second direction y perpendicular to the first surface 515. The first and second trenches 538, 558 may be formed by etch processes, e.g. dry etch processes.

The superjunction semiconductor device 500 further includes a body region 520 of the second conductivity type and a source region 521 of the first conductivity type at the first surface 515, A part of the dielectric 539 between the gate electrode 540 and the body region 520 constitutes a gate dielectric. A conductivity in a channel region along the direction y between the source region 521 and each one of the drift regions 512a . . . 512c can be controlled via a voltage applied to the gate electrode 540. In the embodiment illustrated in FIG. 5, the channel is a vertical channel.

At a second surface 529 of the semiconductor body 505 opposite to the first surface 515, a drain contact 531 is electrically coupled to the drift regions 512a . . . 512c.

Formation of the first semiconductor region 517 and the first and second trenches 538, 558 may be carried out as described with reference to FIG. 1. The first semiconductor region 517 may include one or a plurality of consecutive and overlapping semiconductor zones 509a . . . 509c shaped as bubbles in consecutive epitaxial layers 508a . . . 508c, The number of three epitaxial layers 508a . . . 508c illustrated in FIG. 5 is one example. The number of epitaxial layers may be adapted to the specific requirements and may differ from three, e.g. be smaller than three o larger than three.

As an example, the semiconductor device 500 may include a field plate trench cell structure in the low voltage regime with voltages in a range of 10 V to 100 V. The field plate trench cell structure in FIG. 5 is arranged between compensation structures, e.g. between compensation structure 513a, 513b. The compensation structures 513a, 513b using trenches 558 allow to reduce a cell pitch and, thus, an increase in doping conductivity of the drift regions 512a, 512b, 512c. Thus, the on-state resistance Ron per unit area can be decreased.

According to another embodiment, the first semiconductor region 517 is replaced by a trench including or being filled up with a semiconductor material of the second conductivity type.

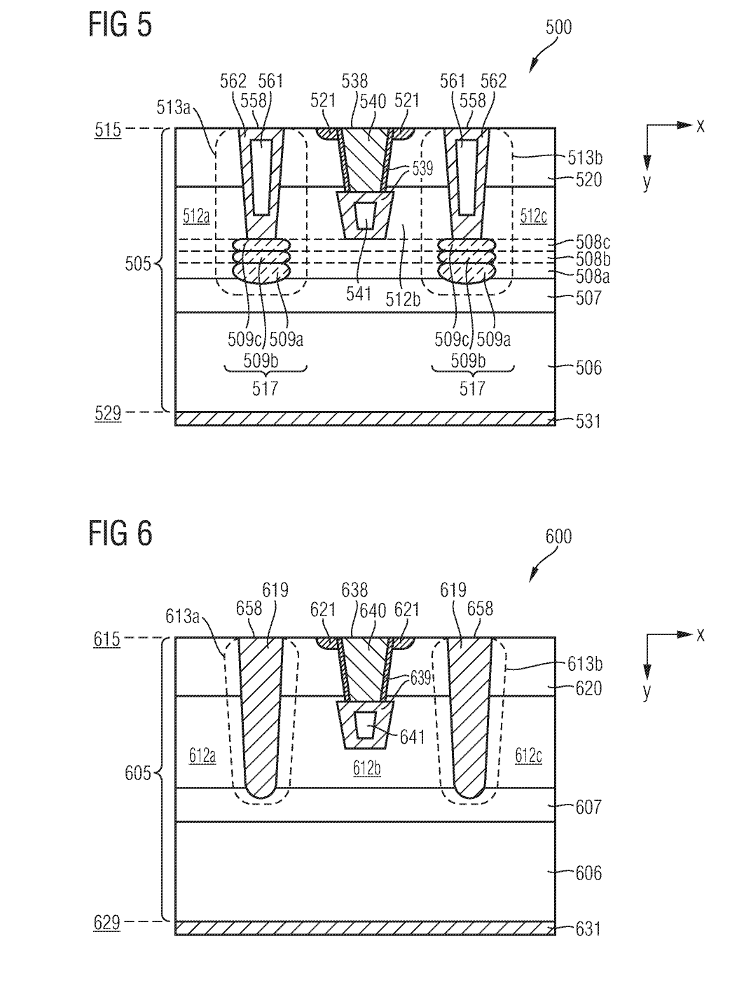

FIG. 6 is a cross sectional view of a superjunction semiconductor device 600 according to another embodiment. The superjunction semiconductor device 600 includes a semiconductor body 605, e.g. a semiconductor substrate 606 including one or more epitaxial layers thereon, e.g. an optional epitaxial base layer 607. According to an embodiment, the semiconductor substrate 600 is made of silicon. According to other embodiments, the semiconductor substrate 606 is made of a material other than silicon.

The superjunction semiconductor device 600 further includes a first trench 638 including a dielectric 639, a gate electrode 640 and a field electrode 641. The first trench 638 extends into the semiconductor body 605 from a first surface 615 of the semiconductor body 605.

A superjunction structure is formed in the semiconductor body 605. The superjunction structure includes drift regions 612a . . . 612c of a first conductivity type and compensation structures 613a, 613b alternately disposed in a first direction x parallel to the first surface 615 of the semiconductor body 605.

Each of the compensation structures 613a, 613b includes a second trench 658 and a second semiconductor region 619 of a second conductivity type complementary to the first conductivity type in the second trench 658. The first and second trenches 638, 658 may be formed by etch processes, e.g. by dry etch processes.

The superjunction semiconductor device 600 further includes a body region 620 of the second conductivity type and a source region 621 of the first conductivity type at the first surface 615. A part of the dielectric 639 between the gate electrode 640 and the body region 620 constitutes a gate dielectric. A conductivity in a channel region along a second direction y between the source region 621 and each one of the drift regions 612a . . . 612c can be controlled via a voltage applied to the gate electrode 640. In the embodiment illustrated in FIG. 6, the channel is a vertical channel.

At a second surface 629 opposite of the semiconductor body 605 to the first surface 615, a drain contact 631 is electrically coupled to the drift regions 612a . . . 612c.

Formation of the second trench 658 and the second semiconductor region 619 may be carried out as described with reference to the first trench 118 and the second semiconductor region 119 in the first trench 118 illustrated in FIG. 1.

The superjunction semiconductor device 600 is beneficial with regard to a compact design. In view of an increased gate to drain capacitance, a screening electrode electrically coupled to a source voltage may be used. Since a compensation effect of the field electrode 641 is of less importance, shallow field plates having a height of less than 75% or 50% of a height of the gate electrode 640 may be used.

In the above-described embodiments, each one of the trenches 118, 218, 318, 328 includes a semiconductor region, e.g. semiconductor regions 119, 219, 319, 329 having a conductivity type equal to the conductivity type of the first semiconductor region 117, 217 317. Thus, the trenches are aligned on the first semiconductor region.

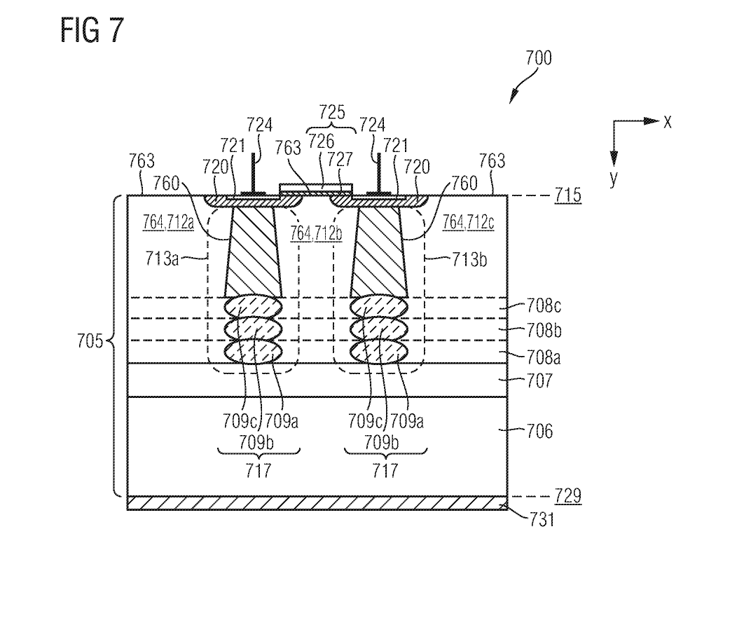

The cross sectional view of FIG. 7 illustrates one further embodiment of a superjunction semiconductor device 700 having a trench compensation structure complementary to the superjunction semiconductor device 100 illustrated in FIG. 1.

Similar to the superjunction semiconductor device 100 illustrated in FIG. 1, the superjunction semiconductor device 700 includes a semiconductor body 705, e.g. a semiconductor substrate 706 with an optional epitaxial base layer 707, a superjunction structure including drift regions 712a . . . 712c of a first conductivity type and compensation structures 713e. 713b alternately disposed in a first direction x parallel to a first surface 715, a body region 720 of a second conductivity type complementary to the first conductivity type and a source region 721 of the first conductivity type at the first surface 715, an electrical contact 724 and a planar gate structure 725 including a gate electrode 726 and a gate dielectric 727 between the gate electrode 726 and the semiconductor body 705.

Each one of the compensation structures 713a, 713b includes a first semiconductor region 717 of a second conductivity type. The first semiconductor region 717 may include one or a plurality of consecutive and overlapping semiconductor zones 709a . . . 709c shaped as bubbles in consecutive epitaxial layers 708a, . . . 708c, The number of three epitaxial layers 708a . . . 708c illustrated in FIG. 7 is one example. The number of epitaxial layers may be adapted to the specific requirements and may differ from three, e.g. be smaller than three or larger than three. Each of the compensation structures 713a, 713b further includes a mesa region 760 of the second conductivity type. Each mesa region 760 is arranged between neighbouring trenches 763. The trenches 763 include a semiconductor region 764 of the first conductivity type that is part of the drift regions 712a, . . . 712c, Whereas the mesa region in the embodiments illustrated in FIGS. 1 to 3 are part of the drift region, the mesa region 760 in the superjunction semiconductor device 700 is part of the compensation structures 713a, 713b, i.e. these embodiments include complementary trench compensation structures.

The above-described complementary trench compensation structure may also be applied to the embodiments illustrated in FIGS. 2 and 3, for example. Discharge of the compensation structures 713a, 713b can be improved via the mesa regions 760, and, thus the switching behaviour can be improved. Thereby, switching losses can be reduced. Widening of the mesa regions 760 along the second direction towards a center of the compensation structures 713a, 713b allows adjusting a profile of an electric field. Thereby, an avalanche characteristic can be improved.

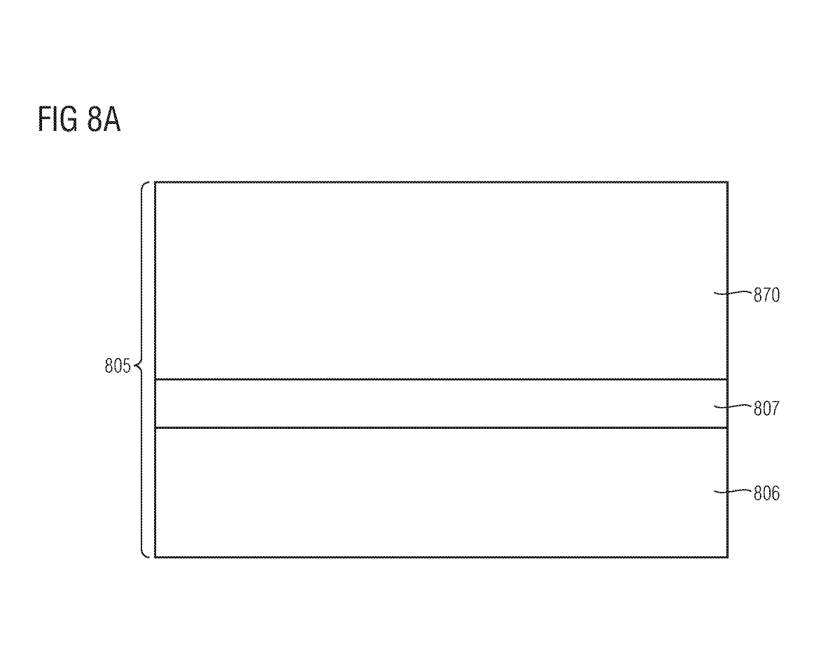

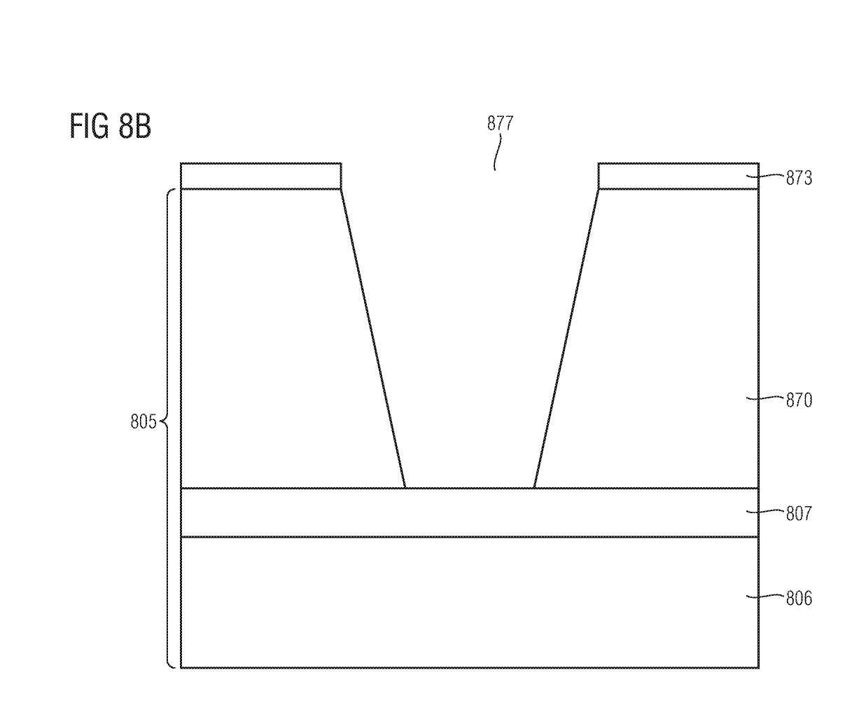

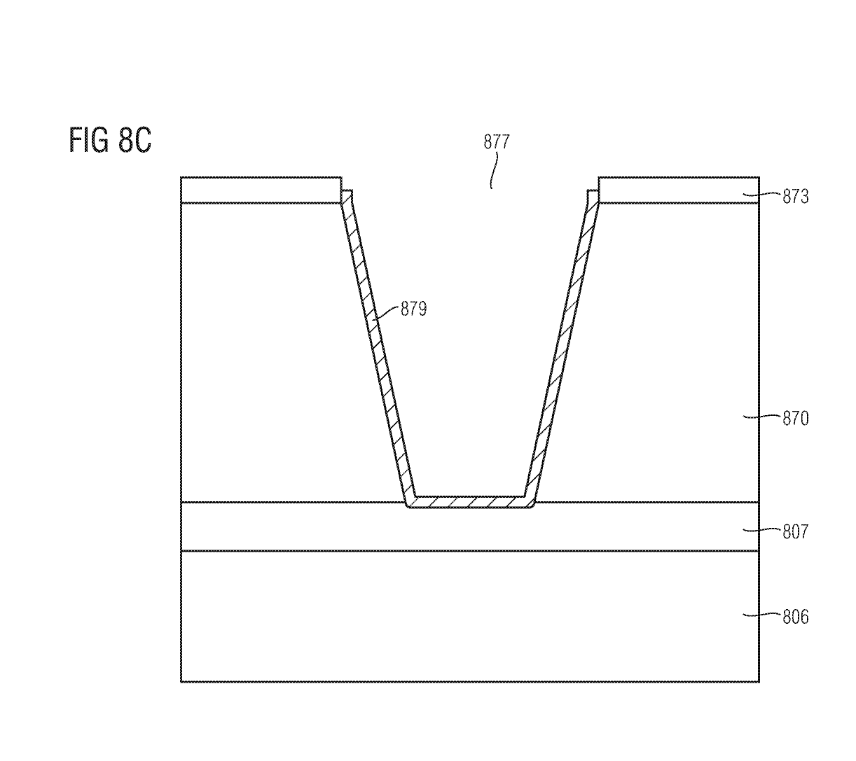

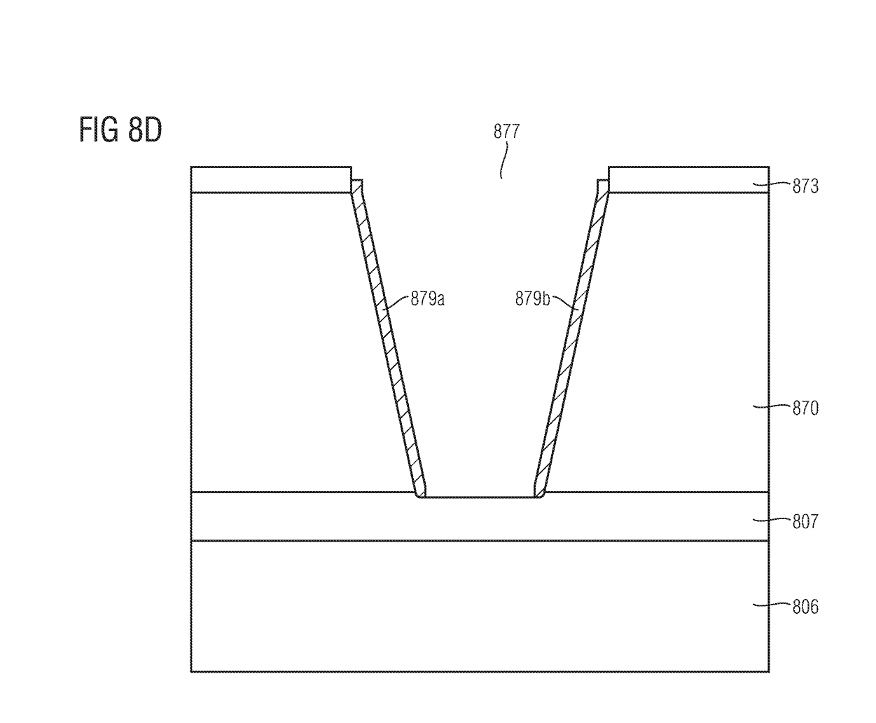

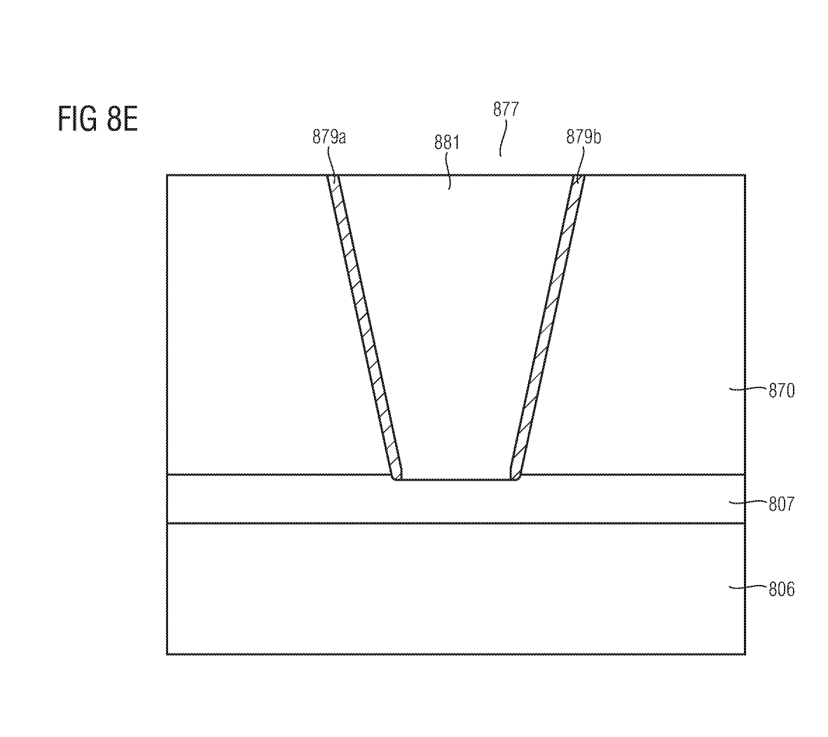

FIGS. 8A to 8E illustrates a schematic process of manufacturing a semiconductor device according to an embodiment.

Referring to the schematic cross sectional view of FIG. 8A, an optional base layer 807 is formed on a semiconductor substrate 806. A semiconductor layer 870 is formed on the optional base layer 807. As an example, a conductivity type of the semiconductor substrate 806, the base layer 807 and the semiconductor layer 870 may be the same, e.g. an n-type or a p-type. The optional base layer 807 and the semiconductor layer 870 may be formed by a layer deposition technique, e. g. epitaxial growth using CVD.

Referring to the schematic cross sectional view of FIG. 8B an etch mask layer is formed on the semiconductor layer 870 and patterned, e.g. by lithography, resulting in an etch mask 873, e.g. an oxide mask. A trench 877 is formed in the semiconductor layer 870, e.g. by a dry etch process. In the embodiment illustrated in FIG. 8B the trench 877 ends at a top side of the optional base layer 807. According to other embodiments, the trench 877 may end within the semiconductor layer 870 or within the semiconductor substrate 806.

Referring to the schematic cross sectional view of FIG. 8C, a doped semiconductor region 879 of a conductivity type complementary to the conductivity type of the semiconductor layer 870 is formed at sidewalls and at a bottom side of the trench 877. The semiconductor region 879 lines the sidewalls and the bottom side of the trench 877. The doped semiconductor region 879 may be formed by selective epitaxy involving e.g. CVD. Doping, e.g. high doping, of the semiconductor region 879 may be carried out in-situ or by ion implantation and thermal activation, for example.

Referring to the schematic cross sectional view of FIG. 8D, the semiconductor region 879 is removed from the bottom side, e.g. by an anisotropic etch process such as dry etching. A first column 879a and a second column 879b of the doped semiconductor region 879 remain at sidewalls of the trench 877 after removal from the trench bottom side.

Referring to the schematic cross sectional view of FIG. 8E, the trench 877 is filled up with a semiconductor material 881 of the first conductivity type. As an example, the doping process and parameters may be set equal to the process and parameters when forming the semiconductor layer 870. The structure may be further processed and end up in a structure similar to FIG. 2. In more detail, the columns 879a and 879b then correspond to the trenches 218 filled with the second semiconductor material 219 of FIG. 2. The left and right part of the semiconductor layer 870 correspond to parts of the drift zones 212a, 212c of FIG. 2 and the semiconductor material of the first conductivity type in the trench 870 corresponds to part of the drift zone 212b of FIG. 2.

The columns 879a, 879b may be combined with any further compensation regions including compensation regions formed by multi epitaxial growth technique. As an example, the columns 879a, 879b may be applied to the embodiments illustrated in FIGS. 1 to 6, for example.

Embodiments of semiconductor devices having sour e and drain, e.g. FETs, have been explained above, but the compensation structures explained above may also be applied to a Schottky Barrier Diode (SBD), a mixed device of FET, e.g. MOSFET, an SBD, an IGBT, when the device has a superjunction structure.

The embodiments described above allow realizing small cell pitches and high aspect ratios of the p-doped and n-doped compensation structures. Further, the doping along a vertical direction, e.g. direction y in FIGS. 1 to 7, may be varied in the compensation structure and thereby the electric field distribution may be adapted to the specific needs of the application.

According to one example, the first conductivity type is a p-type and the second conductivity type is an n-type. According to another example, the first conductivity type is an n-type and the second conductivity type is a p-type.

Terms such as “first”, “second”, and the like, are used to describe various structures, elements, regions, sections, etc. and are not intended to he limiting. Like terms refer to like elements throughout the description.

The terms “having”, “containing”, “including”, “comprising” and the like are open and the terms indicate the presence of stated elements or features, but not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may he substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor body including a first surface and a second surface opposite to the first surface;
a superjunction structure in the semiconductor body, the superjunction structure including drift regions of a first conductivity type and compensation structures alternately disposed in a first direction parallel to the first surface, wherein each of the charge compensation structures includes a first semiconductor region of a second conductivity type complementary to the first conductivity type and a first trench including a second semiconductor region of the second conductivity type adjoining the first semiconductor region;
a body region of the second conductivity type in the semiconductor body; and
a second trench including a third semiconductor region of the second conductivity type in the semiconductor body,
wherein the body region, the first trench, the first semiconductor region and the second trench are disposed one after another in a second direction extending from the first surface to the second surface.

2. The semiconductor device of claim 1, wherein the body region, the third semiconductor region, the first semiconductor region and the second semiconductor region are parts of one continuous semiconductor region of the second conductivity type.

3. The semiconductor device of claim 1, wherein an extension of the first trench along the second direction differs from an extension of the second trench along the second direction by less than 10%.

4. The semiconductor device of claim 1, wherein a profile of doping of the second conductivity type along the second direction between the third semiconductor region and the second semiconductor region includes a peak value in the first semiconductor region.

5. The semiconductor device of claim 1, wherein the semiconductor device is one of an IGBT (insulated gate bipolar transistor), an FET (field effect transistor) or a Schottky barrier diode.

6. A vertical semiconductor device, comprising:
a semiconductor body including a first surface and a second surface opposite to the first surface;
a first trench including a dielectric, a gate electrode and a field electrode, the first trench extending into the semiconductor body from the first surface; and
a superjunction structure in the semiconductor body, the superjunction structure including drift regions of a first conductivity type and compensation structures alternately disposed in a first direction parallel to the first surface.

7. The vertical semiconductor device of claim 6, wherein each of the compensation structures includes the field electrode in the first trench and a first semiconductor region of a second conductivity type complementary to the first conductivity type adjoining the first semiconductor region, and wherein the first semiconductor region is disposed between the first trench and the second surface.

8. The vertical semiconductor device of claim 6, wherein each of the compensation structures includes the field electrode in the first trench and a second trench adjoining the first trench, and wherein the second trench is disposed between the first trench and the second surface and includes a first semiconductor region of a second conductivity type complementary to the first conductivity type.

9. The vertical semiconductor device of claim 6, wherein each of the compensation structures includes:
a second trench extending into the semiconductor body from the first surface, the second trench including a field electrode and a dielectric; and
a first semiconductor region of a second conductivity type complementary to the first conductivity type and adjoining the second trench,
wherein the first semiconductor region and the first trench are disposed one after another in a second direction perpendicular to the first surface.

10. The vertical semiconductor device of claim 6, wherein each of the compensation structures includes:
a second trench extending into the semiconductor body from the first surface, the second trench including a field electrode and a dielectric; and
a third trench in the semiconductor body including a first semiconductor region of a second conductivity type complementary to the first conductivity type,
wherein the second trench and the third trench are disposed one after another in a second direction perpendicular to the first surface.

11. The vertical semiconductor device of claim 6, wherein each of the compensation structures includes:
a second trench extending into the semiconductor body from the first surface, the second trench including a first semiconductor region of a second conductivity type complementary to the first conductivity type,
wherein an extension of the second trench into the semiconductor body from the first surface is larger than an extension of the first trench into the semiconductor body from the first surface.

12. The vertical semiconductor device of claim 6, wherein each of the compensation structures includes:
a first semiconductor region of a second conductivity type complementary to the first conductivity type extending into the semiconductor body from the first surface,
wherein an extension of the second trench into the semiconductor body from the first surface is larger than an extension of the first trench into the semiconductor body from the first surface.
